(19) United States
(12) Patent Application Publication
(10) Pub. No.: US 2009/0061362 A1
(43) Pub. Date: Mar. 5, 2009

(54) SEMICONDUCTOR DEVICE MANUFACTURING METHOD USING DOUBLE PATTERNING AND MASK

(75) Inventors: Hironobu TAOKA, Tokyo (JP); Akemi MONIWA, Tokyo (JP); Junjiro SAKAI, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/200,270

(22) Filed: Aug. 28, 2008

(30) Foreign Application Priority Data
Aug. 29, 2007 (JP) 2007-222512

(51) Int. Cl. G03F 7/20

(52) U.S. Cl. 430/319

(57) ABSTRACT

To provide a semiconductor device manufacturing method using double patterning, in which layout patterns are distributed avoiding yield reduction factors. The semiconductor device manufacturing method includes the steps of: preparing a plurality of masks for use in the double patterning; and performing the double patterning using the plurality of masks. The step of preparing the plurality of masks includes a step of distributing a group of layout patterns to the plurality of masks, in accordance with characteristics of exposure steps respectively using the plurality of masks, and in consideration of size of the layout patterns.

### BACKGROUND OF THE INVENTION

1. Field of the Invention

The present invention relates to a semiconductor device manufacturing method and a mask, and in particular, to a manufacturing method of a semiconductor device having a fine semiconductor circuit pattern and a mask for use in manufacturing the same.

2. Description of the Background Art

As a promising candidate for lithography technique of 32 nm node, double patterning has been proposed. Double patterning is a process for obtaining designed layout patterns, by distributing layout patterns into a plurality of masks and performing a plurality of exposure processes, etching processes and the like. When the distance between two layout patterns is small, if the two layout patterns are formed on an identical mask, the two layout patterns cannot separately be formed on a wafer. Double patterning is used to avoid such a problem.

The layout pattern distribution process is performed as follows, for example. Specifically, based on layout patterns of the processing target and extraction conditions of portions requiring distribution (such as layout pattern size, layout pattern spacing), the portions requiring distribution are extracted. Based on the obtained extraction information (such as coordinates, regions), the layout patterns to be distributed are marked. The marked layout patterns are distributed to different groups of layout patterns. The distributed layout patterns undergo OPC (Optical Proximity Correction) processing, which is a correction that previously takes into account of distortion associated with optical proximity effect. Thereafter, the layout patterns are imaged as masks (for example, see WO 2006/118098).

The conventional distribution of layout patterns to a plurality of masks has been intended to extract locations where designed layout patterns as they are would become problems in manufacturing, and to distribute such layout patterns to a plurality of masks. The conventional technique is acceptable in that it cancels the layout patterns that are critical in manufacturing. However, the conventional technique sometimes distributes layout patterns that actually should not be distributed, thereby undesirably reducing yield. Furthermore, it has not been considered to improve yield in each process after distribution, by the manner of distribution.

### SUMMARY OF THE INVENTION

The present invention has been made in view of the foregoing problems, and one object thereof is to provide a semiconductor device manufacturing method in which layout patterns are distributed so as to avoid yield reducing factors, and a mask for use therein.

Another object of the present invention is to provide a semiconductor device manufacturing method that leverages flexibility obtained by distributing layout patterns to a plurality of masks thereby realizing improved yield, and a mask for use therein.

A semiconductor device manufacturing method according to an embodiment of the present invention is directed to a semiconductor device manufacturing method using double patterning, including the steps of: preparing a plurality of masks for use in the double patterning; and performing the double patterning using the plurality of masks. The step of preparing the plurality of masks includes a step of distributing a group of layout patterns to the plurality of masks, in accordance with characteristics of exposure steps respectively using the plurality of masks, and in consideration of size of the layout patterns.

According to the embodiment, a group of layout patterns can be distributed to a plurality of masks so as to obtain layout patterns with which manufacturing is more facilitated in exposure steps, and so as to exclude layout patterns with which manufacturing is difficult. Thus, manufacturing is facilitated and yield is improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart showing the outline of an LSI manufacturing flow, which is common to embodiments of the present invention.

FIG. 2 is a flowchart showing part of the flow in the wafer process shown in FIG. 1.

FIG. 3 is a schematic diagram showing a configuration of a segmentation/distribution processing system of layout patterns, which is common to the embodiments of the present invention.

FIG. 4 is a flowchart showing a segmentation/distribution processing flow, which is common to the embodiments of the present invention.

FIG. 5 is a schematic diagram showing a group of designed layout patterns of a first embodiment.

FIGS. 6A and 6B are schematic diagrams showing an example of a distributed layout pattern group of the first embodiment.

FIGS. 7A and 7B are schematic diagrams showing other example of a distributed layout pattern group of the first embodiment.

FIG. 8 is a graph showing the relationship between a pitch of layout patterns and the depth of focus.

FIGS. 9A-9C are schematic diagrams showing segmentation/distribution of the layout patterns of a second embodiment.

FIGS. 10A-10D are schematic diagrams for describing conventional subsidiary patterns.

FIG. 11 is a schematic diagram showing an example of a mask in which subsidiary patterns of a third embodiment are formed.

FIG. 12 is a schematic diagram showing an example of dummy patterns for adjusting area ratio.

FIG. 13 is a schematic diagram showing an example of use of subsidiary patterns of greater size.

FIG. 14 is a schematic diagram showing masks in which the layout patterns shown in FIG. 13 are formed.

FIGS. 15A and 15B are schematic diagrams showing a group of layout patterns of a fifth embodiment.

FIG. 16 is a schematic diagram showing an example where subsidiary patterns distributed to the same mask as layout patterns having relatively high manufacturing accuracy requirement are added.

FIGS. 17A and 17B are schematic diagrams showing a group of layout patterns of a seventh embodiment.

FIG. 18 is a schematic diagram showing an example of segmentation where a hole pattern is formed on a layout pattern.

FIG. 19 is a schematic diagram showing designed layout patterns of a ninth embodiment.

FIGS. 20A and 20B are schematic diagrams showing a scheme where adjacent layout patterns are not distributed to different masks.

FIGS. 21A and 21B are schematic diagrams showing a scheme where non-adjacent layout patterns are not distributed to different masks.

FIG. 22 is a schematic diagram for describing a method of setting the origin of search for a segmentation line in accordance with the distance from the side of an adjacent layout pattern.

FIG. 23 is a schematic diagram showing the method of setting the origin of search for a segmentation line shown in FIG. 22, to which non-manufacturable pattern size is added.

FIG. 24 is a schematic diagram for describing a method of setting the origin of search for a segmentation line for each layout pattern type and size.

### DESCRIPTION OF THE PREFERRED EMBODIMENTS

In the following, embodiments of the present invention will be described based on the drawings.

### First Embodiment

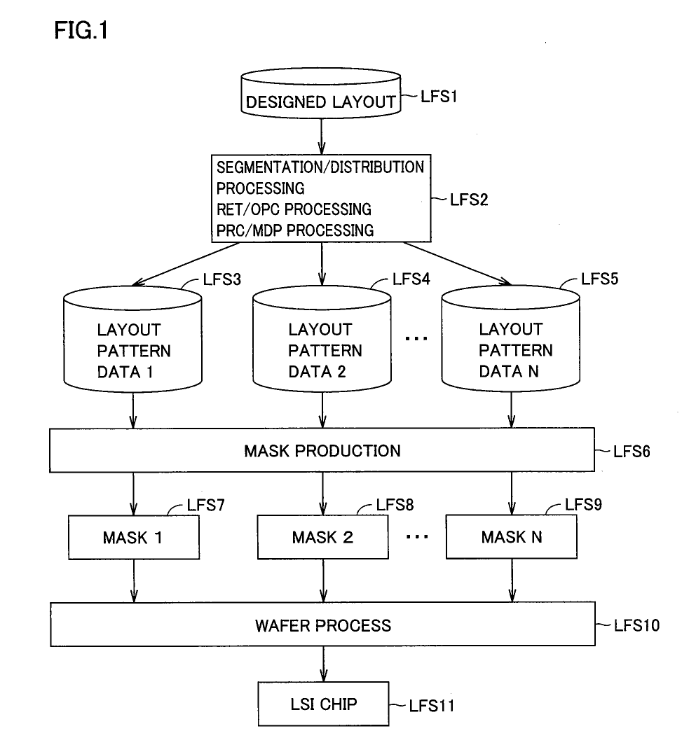

FIG. 1 shows a semiconductor device manufacturing method using double patterning. As shown in FIG. 1, in an LSI manufacturing flow of the present embodiment, firstly an intended designed layout is determined (LFS1). Next, in step (LFS2), segmentation/distribution processing, RET (Resolution Enhancement Technique), OPC (Optical Proximity Correction) processing, PRC (Process Rule Check), MDP (Mask Data Preparation) processing and the like are provided to the designed layout. Thus, layout pattern data 1, 2 . . . N is obtained (LFS 3-5). It should be noted that, as used herein, the optical proximity correction refers not only to optical proximity effect, but also to various pattern distortions in manufacturing. PRC refers to detection of problems in manufacturing, such as lithography verification that detects problems in a lithography process, MRC (Mask Rule Check) that detects problems in a mask process, and check for conditions that must be satisfied in imaging.

Next, in step (LFS6), masks are produced for the obtained layout patterns. Specifically, in step (LFS6), a plurality of masks for use in double patterning are prepared. Then, masks 1, 2, . . . N corresponding to respective layout patterns are obtained (LFS7-9). Next, in step (LFS10), a wafer process is performed using the masks. Specifically, double patterning is performed in step (LFS10), wherein exposure, etching and the like are performed for a plurality of times using the plurality of masks prepared in step (LFS6) to thereby obtain the designed layout patterns. After the required structure is formed on a wafer by this double patterning, post-processes such as a dicing process are performed. In this manner, an LSI chip as a semiconductor device is obtained (LFS11).

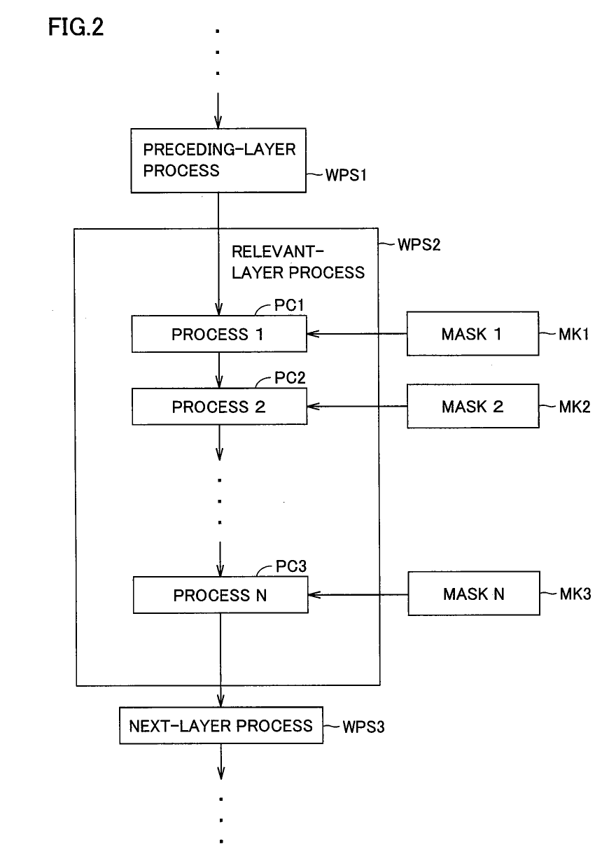

In wafer process (LFS10) shown in FIG. 1, as shown in FIG. 2, before a relevant-layer process (WPS2) for a certain layer is performed, a preceding-layer process (WPS1) for a layer preceding the relevant layer is performed. Also, after relevant-layer process (WPS2) is performed, a next-layer process (WPS3) for a layer following the relevant layer is performed. In order to form patterns of the relevant layer on a wafer, a plurality of processes 1, 2, . . . N (PC1-3 in FIG. 2) respectively using a plurality of masks 1, 2 . . . N (MK1-3 in FIG. 2) are performed. By processes 1, 2, . . . N, the wafer patterns corresponding to masks 1-N are formed on a wafer, resist, hard mask and the like. Ultimately, after process N, wafer patterns having the shape corresponding to the relevant-layer patterns of the designed layout are obtained. It is to be noted that processes 1-N include required pre- and post-processes.

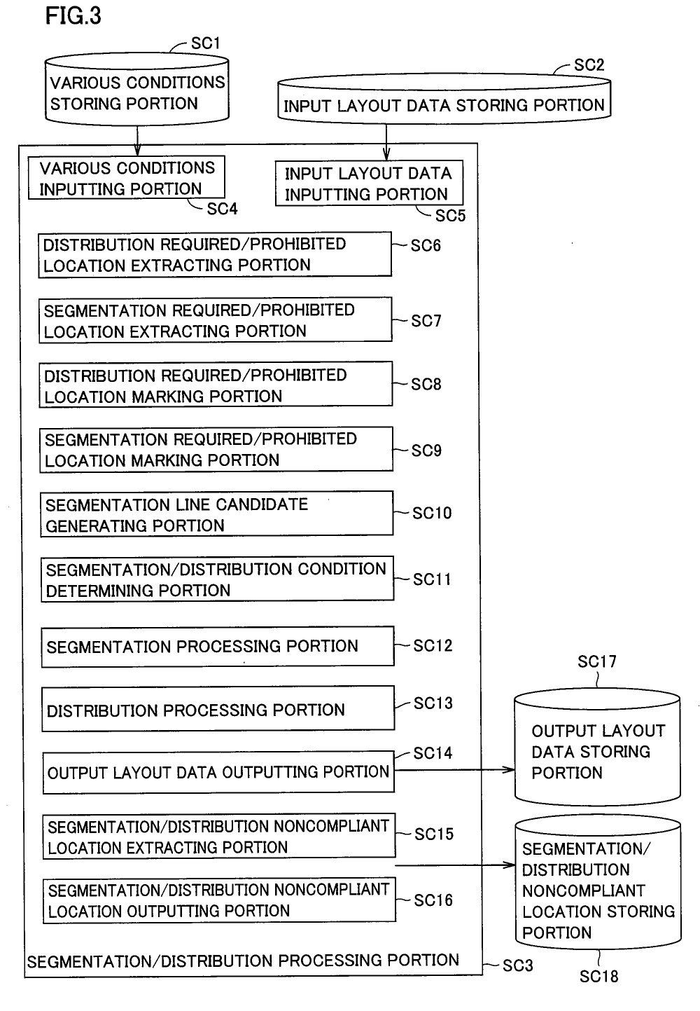

As shown in FIG. 3, in a layout pattern segmentation/distribution processing system used in step (LFS2) shown in FIG. 1, required data is input to a segmentation/distribution processing portion SC3 from a various conditions storing portion SC1 that stores data including various conditions for processing (such as conditions required for distribution processing, e.g., a non-manufacturable distance, conditions required for segmentation processing, and layer information of an input layout) and an input layout data storing portion SC2 that stores data expressing an input layout pattern. The segmentation/distribution processing system further includes an output layout data storing portion SC17 that stores data expressing an output layout pattern, that is a result of the segmentation/distribution processing. The segmentation/distribution processing system further includes a segmentation/distribution noncompliant location storing portion SC18 that stores data including a location that is not compliant with enforcement/prohibition of segmentation/distribution, which is left after segmentation/distribution, and extraction conditions therefor. It is to be noted that various conditions storing portion SC1, input layout data storing portion SC2, output layout data storing portion SC17, and segmentation/distribution noncompliant location storing portion SC18 may physically and logically be singular or may be plural.

Segmentation/distribution processing portion SC3 includes a various conditions inputting portion SC4 to which data is input from various conditions storing portion SC1, and an input layout data inputting portion SC5 to which data is input from input layout data storing portion SC2. Segmentation/distribution processing portion SC3 further includes a distribution required/prohibited location extracting portion SC6 that extracts a location where distribution is required/prohibited, a segmentation required/prohibited location extracting portion SC7 that extracts a location where segmentation is required/prohibited, a distribution required/prohibited location marking portion SC8 that marks locations where distribution is required/prohibited, and a segmentation required/prohibited location marking portion SC9 that marks locations where segmentation is required/prohibited. Segmentation/distribution processing portion SC3 further includes a segmentation line candidate generating portion SC10 that generates a candidate for a segmentation line, a segmentation/distribution condition determining portion SC11 that determines segmentation/distribution conditions, a segmentation processing portion SC12 that performs segmentation processing, and a distribution processing portion SC13 that performs distribution processing.

Segmentation/distribution processing portion SC3 further includes an output layout data outputting portion SC14, a segmentation/distribution noncompliant location extracting portion SC15, and a segmentation/distribution noncompliant location outputting portion SC16. Output layout data outputting portion SC14 outputs data to output layout data storing portion SC17. Segmentation/distribution noncompliant location extracting portion SC15 and segmentation/distribution noncompliant location outputting portion SC16 extract a location that is not compliant with enforcement/prohibition of segmentation and enforcement/prohibition of distribution, and output data to segmentation/distribution noncompliant location storing portion SC18.

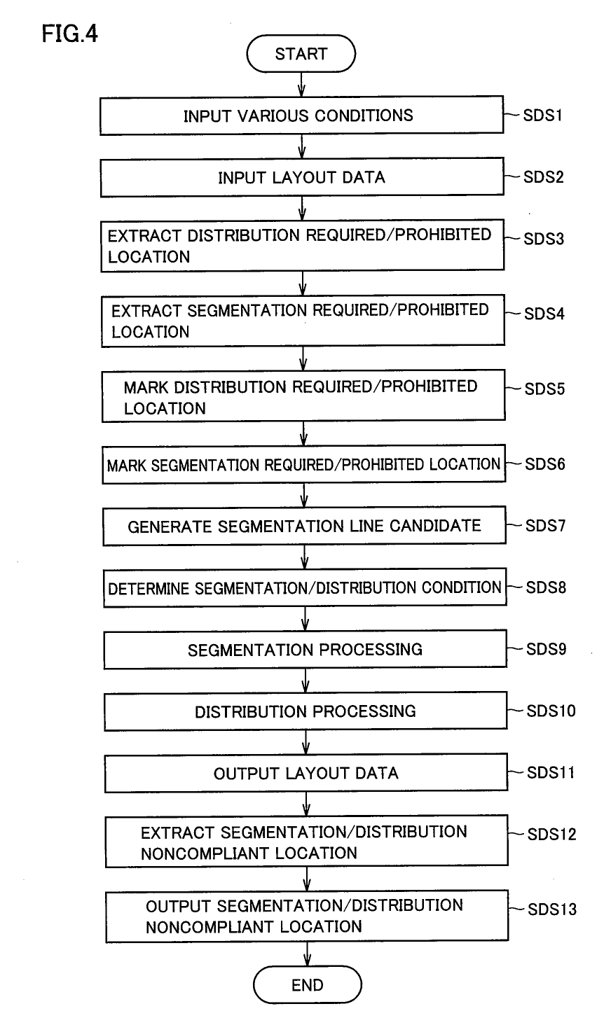

As shown in FIG. 4, in a segmentation/distribution processing flow of the present embodiment, which is part of step (LFS2) shown in FIG. 1, first, in a various conditions inputting step (SDS1), the various conditions stored in various conditions storing portion SC1 in FIG. 3 are read into various conditions inputting portion SC4 in FIG. 3. Specifically, what are read are: conditions designating layout patterns of layout data (such as a cell name, a layer name, a processing region); conditions required for each processing, such as extraction of distribution, segmentation and segmentation/distribution noncompliant locations; and a layout data output instruction to output layout data storing portion SC17 and to segmentation/distribution noncompliant location storing portion SC18. Next, in a layout data inputting step (SDS2), based on the information being input in various conditions inputting step (SDS1), required layout pattern data is read from input layout data storing portion SC2 in FIG. 3 into input layout data inputting portion SC5.

Next, in a distribution required/prohibited location extracting step (SDS3), in distribution required/prohibited location extracting portion SC6 in FIG. 3, a distribution required location and a distribution prohibited location are extracted from layout patterns, which are the target of processing. The extraction of distribution required/prohibited location is performed based on the processing-target layout patterns, the reference layout patterns, and the distribution required/prohibited location extraction conditions (such as layout pattern size, layout pattern spacing, and positional information showing extraction locations contained in input layout data storing portion SC2 in FIG. 3) read in various conditions inputting step (SDS1).

Next, in a segmentation required/prohibited location extracting step (SDS4), in segmentation required/prohibited location extracting portion SC7 in FIG. 3, a segmentation required location and a segmentation prohibited location are extracted from the processing-target layout patterns. The extraction of segmentation required/prohibited location is performed based on the processing-target layout patterns, the reference layout patterns, and the segmentation required/prohibited location extraction conditions (such as positional information showing extraction locations contained in input layout data storing portion SC2 in FIG. 3) read in various conditions inputting step (SDS1).

Next, in a distribution required/prohibited location marking step (SDS5), in distribution required/prohibited location marking portion SC8 in FIG. 3, layout patterns to be distributed to different groups of layout patterns, and layout patterns that are not to be distributed to different groups of layout patterns and to be classified into a group of identical layout patterns are respectively associated (marked) with data of the processing-target layout patterns. The marking of distribution required/prohibited locations is performed based on the distribution required/prohibited location marking conditions (such as an association method used in marking) read in various conditions inputting step (SDS1), and based on extraction information (such as coordinates and regions) obtained in distribution required/prohibited location extracting step (SDS3).

Next, in a segmentation required/prohibited location marking step (SDS6), in segmentation required/prohibited location marking portion SC9 in FIG. 3, a position to perform segmentation by separating the layout pattern(s) forming a single polygonal shape into a plurality of layout patterns is set (marked) to the data of the processing-target layout patterns. Also, a segmentation prohibited location is set (marked), on the layout-pattern polygonal shape basis, or as a segmentation prohibited region. The marking of segmentation required/prohibited location is performed based on the segmentation required/prohibited location marking conditions (such as a method of designating a segmentation line used in marking) that are read in various conditions inputting step (SDS1), and based on extraction information (such as coordinates, regions and lines) obtained in segmentation required/prohibited location extracting step (SDS4).

Next, in a segmentation line candidate generating step (SDS7), in segmentation line candidate generating portion SC10 in FIG. 3, a candidate for a position of one end of a segmentation line (segmentation mark) is arranged at, for example, a vertex of a layout pattern and where a perpendicular line is drawn from a vertex of an adjacent layout pattern. This segmentation mark is considered as an origin point for searching for the position where the segmentation line is to be arranged in the layout patterns. Also, for example, the origin point for searching for the segmentation line is set in accordance with the distance from the adjacent layout pattern. Thus, the candidate for the segmentation line is generated.

Next, in a segmentation/distribution condition determining step (SDS8), in segmentation/distribution condition determining portion SC11 in FIG. 3, the segmentation line is selected by a method using simulation, a method employing cost-minimizing algorithm and the like. Based on the selected segmentation line, and the distribution required location of the layout patterns having been associated in distribution required/prohibited location marking step (SDS5), the segmentation/distribution condition is determined.

Next, in a segmentation processing step (SDS9), in segmentation processing portion SC12 in FIG. 3, the layout patterns are segmented at the location marked as segmentation-required in segmentation required/prohibited location marking step (SDS6). Segmentation of the layout patterns is not performed at the location marked as segmentation-prohibited.

Next, in a distribution processing step (SDS10), in distribution processing portion SC13 in FIG. 3, the layout patterns having been marked and associated in distribution required/prohibited location marking step (SDS5) are distributed to different groups of layout patterns. At the location marked as distribution-prohibited, the layout patterns are classified into an identical group of layout patterns.

Next, in a layout pattern data outputting step (SDS11), in output layout data outputting portion SC14 in FIG. 3, based on a layout output content, an output-recipient condition and the like read in various conditions inputting step (SDS1), the layout data obtained as a result of segmentation processing step (SDS9) and distribution processing step (SDS10) is output to output layout data storing portion SC17 in FIG. 3. Here, an intermediate result of the other steps (from distribution required/prohibited location extracting step (SDS3) to segmentation required/prohibited location marking step (SDS6)) may be output. Furthermore, between any two of these steps, processing of graphical operations performed by a DRC (Design Rule Check) tool, such as sizing, logical operations or the like, may be carried out.

Next, in a segmentation/distribution noncompliant location extracting step in (SDS12), segmentation/distribution noncompliant location extracting portion SC15 in FIG. 3, a segmentation/distribution noncompliant location that fails to satisfy the segmentation and distribution conditions for a result of segmentation processing step (SDS9) and distribution processing step (SDS10) is extracted. Extraction of the segmentation/distribution noncompliant location is performed based on the segmentation/distribution noncompliant location extracting condition (such as segmentation/distribution noncompliant location extracting condition, the number of layout patterns adjacent to the segmentation/distribution noncompliant location mark) read in various conditions inputting step (SDS1).

Next, in a segmentation/distribution noncompliant location outputting step (SDS13), in segmentation/distribution noncompliant location outputting portion SC16 in FIG. 3, the segmentation/distribution noncompliant location information (such as content of noncompliance, coordinates, and region) obtained in segmentation/distribution noncompliant location extracting step (SDS12) is output to segmentation/distribution noncompliant location storing portion SC18 in FIG. 3, based on the segmentation/distribution noncompliance output content and output-recipient condition read in various conditions inputting step (SDS1). Thus, the segmentation/distribution processing ends.

It is to be noted that, after the layout patterns are distributed to a plurality of masks, it is necessary to perform graphical processing generally performed before mask formation, such as creation of CMP (Chemical Mechanical Polishing) dummy patterns, OPC processing, RET-related operations to dummy patterns and layout. They are performed to the required portions at required timing.

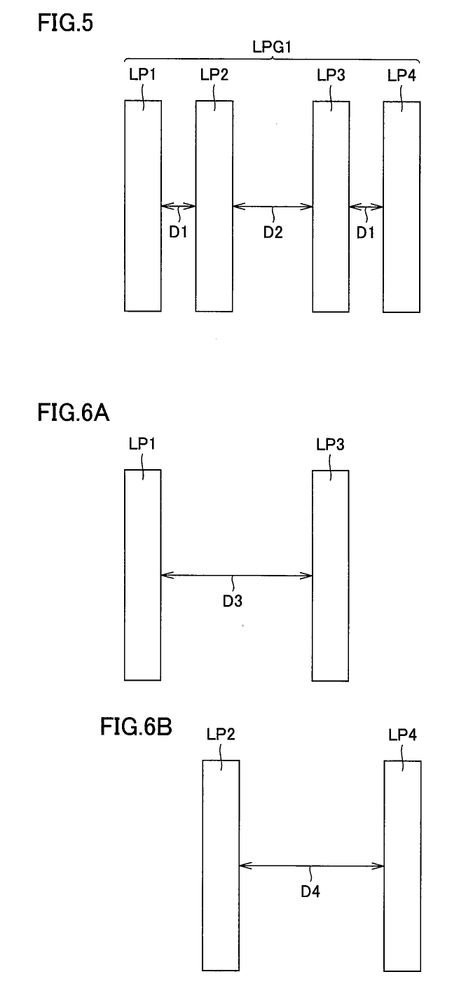

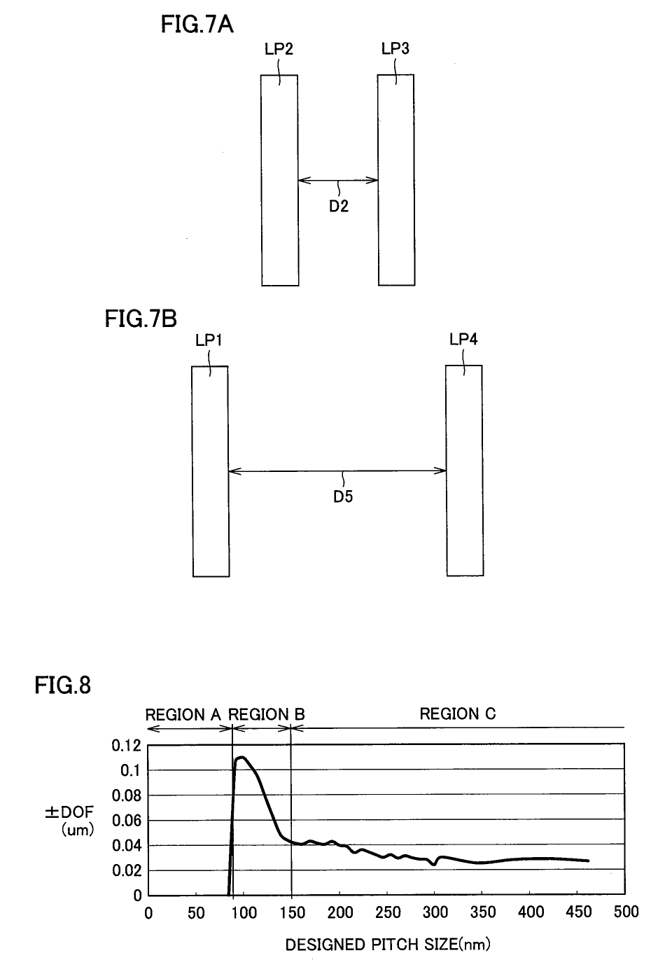

Next, a specific example of distribution processing performed in segmentation/distribution condition determining step (SDS8) shown in FIG. 4 will be described. As shown in FIG. 5, a layout pattern group LPG1, which is a designed layout pattern group, is formed by layout patterns LP1-LP4. A distance D1 is a distance with which the layout patterns cannot separately be formed (transferred) on a wafer. A distance D2 is a distance with which the layout patterns can separately be formed on a wafer. In order to prevent each distance between layout patterns LP1-LP4 from becoming distance D1, there are two possible methods of distributing layout pattern group LPG1 to a plurality of masks, one being a method of carrying out distribution as shown in FIGS. 6A and 6B, and the other being a method of carrying out distribution as shown in FIGS. 7A and 7B.

Layout pattern group LPG1 shown in FIG. 5 can be distributed to layout patterns LP1, LP3 shown in FIG. 6A and layout patterns LP2, LP4 shown in FIG. 6B. Distances D3 and D4 are the distances with which layout patterns can separately be formed on a wafer. Accordingly, by overlapping the distribution results shown in FIGS. 6A and 6B, layout pattern group LPG1 shown in FIG. 5, which is the desired designed layout pattern group, can be obtained.

On the other hand, layout pattern group LPG1 shown in FIG. 5 can be distributed to layout patterns LP2, LP3 shown in FIG. 7A and layout patterns LP1, LP4 shown in FIG. 7B. Distances D2 and D5 are the distances with which layout patterns can separately be formed on a wafer. Accordingly, by overlapping the distribution results shown in FIGS. 7A and 7B, layout pattern group LPG1 shown in FIG. 5, which is the desired designed layout pattern group, can be obtained.

The distributed layout pattern groups shown in FIGS. 6A and 6B and FIGS. 7A and 7B are each the case where layout pattern group LPG1 corresponding to the designed layout patterns can be formed on a wafer. Here, generally the manufacturability in the lithography technique depends on the pitch of layout patterns (that is, a distance (spacing) between adjacent layout patterns). Accordingly, even when the pitch of the layout patterns are the distance with which the layout patterns can separately be formed on a wafer, yield will be different in accordance with the distance between the layout patterns. Conventionally, distribution has not been performed by distinguishing the distribution method shown in FIGS. 6A, 6B from that shown in FIGS. 7A, 7B. However, in the present embodiment, distribution is performed by distinguishing those methods from each other.

For example, when normal lithography technique is used, generally manufacturing is more difficult as the pitch of the layout patterns is smaller. When manufacturing of layout patterns LP2 and LP3 having distance D2, which is relatively small among distances D2-D5, is difficult, this is taken into account and distribution shown in FIGS. 6A and 6B is performed. Thus, it becomes unnecessary to form layout patterns on a wafer having the pitch of distance D2, with which manufacturing is difficult if not impossible. As a result, manufacturing is facilitated and yield is improved.

Also, for example when lithography technique that facilitates manufacturing of layout patterns arranged with a particular pitch, such as off-axis illumination, is used, generally manufacturing with an intermediate pitch being different from the particular pitch is most difficult. When D3 and D4 correspond to the intermediate pitch among distances D2-D5, and manufacturing of layout patterns LP1 and LP3 having a spacing of D3 and layout patterns LP2 and LP4 having a spacing of D4 is difficult, this is taken into account and distribution shown in FIGS. 7A and 7B is performed. Thus, it becomes unnecessary to form layout patterns on a wafer having the pitch of distances D3 and D4, with which manufacturing is difficult if not impossible. As a result, manufacturing is facilitated and yield is improved.

Also, for example when lithography technique that facilitates manufacturing of layout patterns arranged with a pitch, which is a distance not smaller than the distance with which layout patterns can separately be formed on a wafer and that is smaller than distance D5 (excluding distance D5), is used, manufacturing of layout patterns LP1 and LP4 having a spacing of great distance D5 is difficult. This is taken into account and distribution as shown in FIGS. 6A and 6B is performed. Thus, it becomes unnecessary to form layout patterns on a wafer having the pitch of distance D5, with which manufacturing is difficult if not impossible. As a result, manufacturing is facilitated and yield is improved.

Also, for example when lithography technique of facilitating manufacturing of the pattern pitches of distances D3 and D4 is used, even when distance D2 is a distance with which layout patterns can separately be formed on a wafer, this is taken into account and distribution shown in FIGS. 6A and 6B is performed. Thus, it becomes unnecessary to form the layout patterns on a wafer having distances D2 and D5 as the pitches, with which manufacturing is difficult if not impossible. As a result, manufacturing is more facilitated and yield is improved.

Also, for example, particularly in the lithography technique, the effect of overlapping a plurality of masks and changes in the pattern size will be described. When distributing layout patterns to a plurality of masks and carrying out manufacturing with a plurality of processes, if there is displacement in the positional relationship among the distributed layout patterns due to overlap displacement among the plurality of masks, the distance between the layout patterns is changed to a value different from the designed layout patterns. The distance between the layout patterns is changed to a value different from the designed layout patterns also by a change in the pattern size. The capacity between the layout patterns is dependent on this distance. As the distance is smaller, the capacity becomes greater, and the effect to the capacity by a change in the distance becomes greater. Thus, in manufacturing layout patterns LP2 and LP3 having a spacing of distance D2, which is relatively small among distances D2-D5, when the effect of changes in the distance between the layout patterns to the capacity is great, this is taken into account and distribution shown in FIGS. 6A and 6B is performed. Thus, it becomes unnecessary to form the layout patterns on a wafer having distance D2 as the pitch, which is relatively small as a distance between layout patterns. As a result, manufacturing is facilitated and yield is improved.

As described above, a layout pattern group can be distributed to a plurality of masks so as to obtain layout patterns having a pitch of a distance with which manufacturing is more facilitated in the lithography technique, and so as to exclude layout patterns having a pitch of a distance with which manufacturing is difficult. Specifically, as described with reference to FIG. 1, in double patterning, exposure is performed for a plurality of times. In the exposure steps, the plurality of masks to which the layout pattern group is distributed are respectively used. The exposure steps are characterized in that they are different in manufacturability for a pitch between layout patterns. The layout pattern group can be distributed to a plurality of masks considering the pitch between the layout patterns determined by the size and arrangement of the payout patterns, in accordance with the characteristic of a particular exposure step. Thus, manufacturing is facilitated and yield is improved. It is apparent that the similar effect is attained when the present invention is applied to a case where the number of distribution is greater than two.

Here, the relationship between the pitch of layout patterns and the necessity of distribution of a layout pattern group will be described. The horizontal axis in FIG. 8 indicates size of the pitch of designed layout patterns (unit: nm) and the vertical axis indicates the DOF (Depth of Focus) (unit: μm). FIG. 8 shows the DOF in a 45 nm resist pattern formation process, using an ArF liquid immersion exposure machine, NA=1.3, ⅔ annular illumination, and a clear field mask.

In region A shown in FIG. 8, since the layout patterns do not resolve if not being segmented, segmentation of the layout pattern group is essential. Region B shows a range where the designed pitch size is not greater than about 150 nm, ranging from resolution limit size (λ/NA/2=193/1.3/2) to the minimum pitch of three luminous flux (λ/NA=193/1.3). In region B, it is more advantageous to arrange the layout pattern group in one mask, since a DOF margin can be attained. Specifically, in region B, it is more advantageous to form the layout patterns on one mask, for example using the off-axis illumination or the like, instead of segmenting the layout pattern group in double patterning. In region C, the layout pattern group may be distributed or not be distributed.

### Second Embodiment

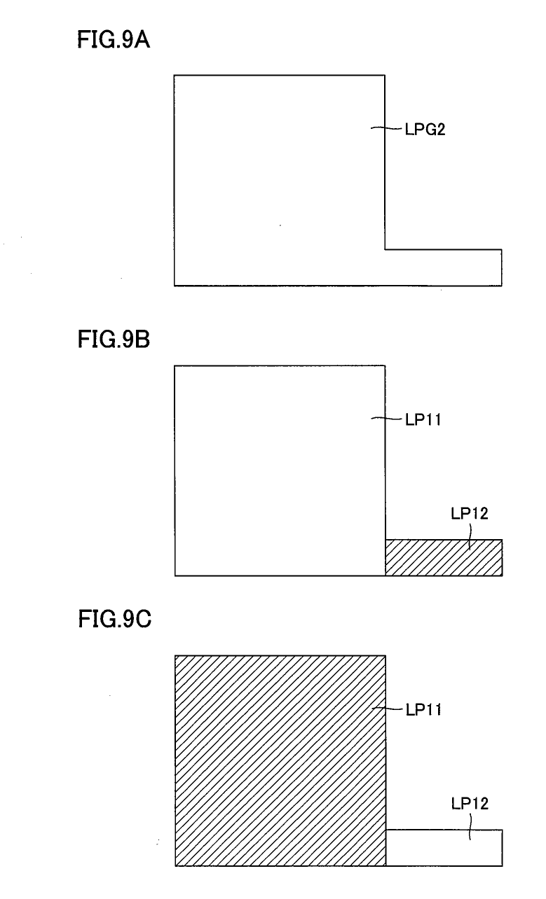

In the present embodiment, description will be given as to another example of distributing designed layout pattern to a plurality of masks that is performed in segmentation/distribution condition determining step (SDS8) shown in FIG. 4. This is an example being different from the first embodiment, in which originally separated designed layout patterns are distributed to a plurality of masks. Here, a designed layout pattern that is not originally separated is segmented into a plurality of layout patterns, and thereafter distributed to a plurality of masks. Also herein, layout patterns are distinguishably allotted to the masks. FIG. 9A shows a layout pattern group LPG2 that is the designed layout pattern. FIGS. 9B and 9C are schematic views showing examples where layout pattern group LPG2 is segmented at the identical location to obtain layout patterns LP11 and LP12.

In FIG. 9B, out of the segmented layout patterns LP11 and LP12, layout pattern LP11 that is relatively greater in size and has greater width and area is allotted to a first mask. On the other hand, layout pattern LP12 that is relatively smaller in size and has smaller width and area is allotted to a second mask, as indicated by the hatched portion. Referring to FIG. 9C, layout pattern LP12 is allotted to a first mask, while layout pattern LP11 indicated by the hatched portion is allotted to a second mask.

In some cases, the processes using the first and second masks may not completely be reversible. Specifically, in some cases, when the sequential relationship between the processes is reversed, manufacturing may become difficult. For example, there may be some cases where the area ratio or width of a layout pattern should be increased or reduced in the process of using the first mask, in accordance with the characteristic of etching processes where etching masks formed by using the first and second masks as a plurality of masks are used. Accordingly, when the area ratio or width of a layout pattern should be increased in the process of using the first mask, as shown in FIG. 9B, the layout pattern group is distributed such that layout pattern LP11 is allotted to the first mask. When the area ratio or width of a layout pattern should be reduced in the process of using the first mask, as shown in FIG. 9C, the layout pattern group is distributed such that layout pattern LP12 is allotted to the first mask. As used herein, the area ratio of a layout pattern refers to the ratio of the occupying area of a layout pattern formed in a mask to the area of the whole mask.

Thus, by distributing the layout pattern group into a plurality of masks considering the size of layout patterns, or taking greatness/smallness of the width of layout patterns as criterion, manufacturing is facilitated and yield can be improved. While an example where segmentation and distribution are performed has been described in the present embodiment, a case where segmentation is not performed is similar in determining whether originally separated layout patterns are to be distributed to the first mask or the second mask. Also, while distribution taking the size or width of layout patterns as criterion has been described in the present embodiment, distribution taking the pitch of layout patterns as criterion as described in the first embodiment can attain the similar effect. It is apparent that the similar effect is attained when the present invention is applied to a case where the number of distribution is greater than two.

### Third Embodiment

In the present embodiment, description will be given as to an example where a subsidiary pattern is formed in a mask in addition to the layout patterns in segmentation/distribution condition determining step (SDS8) shown in FIG. 4. A subsidiary pattern refers to a pattern added to original designed layout patterns in order to obtain a pattern pitch or a pattern density that is desirable in manufacturing. Addition of the subsidiary pattern achieves the effect such as improved resolution or increased depth of focus, whereby the pattern shape can be improved.

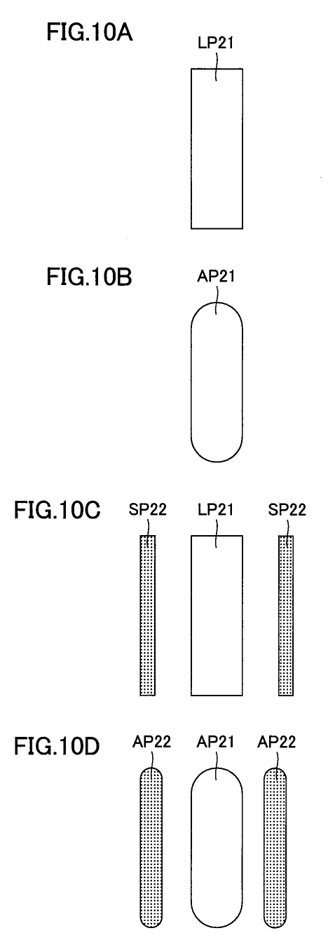

FIG. 10A shows a layout pattern LP21 as a designed layout pattern. FIG. 10B shows a pattern AP21 that is actually obtained on a wafer for layout pattern LP21 in FIG. 10A.

FIG. 10C shows an example where a subsidiary pattern SP22 is added to FIG. 10A. When broadly classified, the subsidiary pattern includes a non-resolving subsidiary pattern with which only the pattern such as pattern AP21 shown in FIG. 10B is obtained on a wafer, and a resolving subsidiary pattern with which patterns formed by AP 21 and AP 22 shown in FIG. 10D are obtained on a wafer. The difference between them lies in that the size of subsidiary pattern SP22 shown in FIG. 10C is greater or smaller than the resolvable size with lithography technique. When the size of subsidiary pattern SP22 is great, it resolves as a pattern also on a wafer, as AP22 in FIG. 10D. When the size of subsidiary pattern SP22 is small, as shown in FIG. 10B, a pattern is not formed at the portion corresponding to subsidiary pattern SP22 on a wafer.

Generally, the greater the size of a subsidiary pattern, the greater the effect to improvement in the DOF margin or an increase in the area density. Therefore, it is preferable in manufacturing to use subsidiary pattern SP22 having a greater size, as shown in FIG. 10D, with which pattern AP22 is resolved on a wafer. However, in the conventional method, this cannot be employed if pattern AP 22 resolved by subsidiary pattern SP22 adversely affects the device or circuitry by remaining on a wafer. Accordingly, there has been a problem that the arrangement location of subsidiary pattern SP22 is restricted and subsidiary pattern SP22 cannot be placed at many locations.

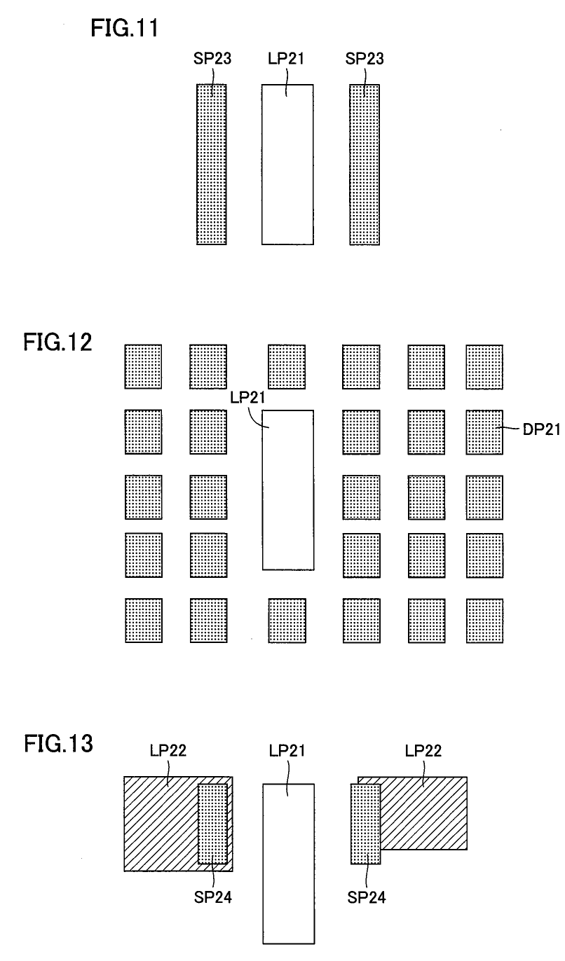

Then, in the present embodiment, description will be given as to an example where a subsidiary pattern formed to have a size resolvable on a substrate (wafer) is used. In FIG. 11, in addition to layout pattern LP21 also shown in FIG. 10A, a subsidiary pattern SP23 having the size resolvable on a wafer is formed. The difference from FIG. 10C is that the size of subsidiary pattern SP23 is greater than subsidiary pattern SP22. When subsidiary pattern SP23 having the size resolvable on a wafer is used, the size and position of subsidiary pattern SP23 should be determined such that the trace of subsidiary pattern SP23 resolved on a wafer disappears in a step after subsidiary pattern SP23 has resolved. Thus, an event where the pattern resolved by subsidiary pattern SP23 remains on the wafer thereby adversely affecting the device and circuitry can be avoided.

For example, when repeating a manufacturing process where a process using a first mask is performed and thereafter a process using a second mask is performed, sometimes a process using a hard mask is employed. In the process of using the first mask, the trace of a subsidiary pattern remains on the resist after development. However, thereafter if the trace of the subsidiary pattern disappears in a step of, for example, etching the hard mask, use of the subsidiary pattern having the size with which trace is left on the resist does not ultimately leave trace on the wafer.

More specifically, an SRAF (Sub-Resolution Assist Feature) pattern of the first mask is set to have a greater size, and the trace of the SRAF pattern is allowed to remain in a first processing step using the first mask. Thereafter, in a second processing step using the second mask, by erasing the SRAF pattern remained in the first processing step, a wafer where trace of the SRAF pattern is not ultimately left can be obtained.

A specific example of the present embodiment is shown in the following. The shown example is a 45 nm resist pattern formation process, using ArF liquid immersion exposure machine, NA=1.3, ⅔ annular illumination, and a clear field mask. In a case where SRAF size of the first mask is 28 nm, DOF in an isolated pattern is ±0.032 μm. When SRAF size is 35 nm, DOF is increased to ±0.039 μm. Specifically, increasing the SRAF in size, the depth of focus is increased. Furthermore, when SRAF size is 35 nm, though trace of about 10 nm width was left on a wafer after the first processing step, this trace disappeared after the second processing step (etching step).

As described above, even when subsidiary pattern SP23 having great size and greater effect is added, a pattern such as shown in FIG. 10B where pattern AP22 shown in FIG. 10D does not remain on a wafer can be obtained. Thus, while avoiding the problem that the pattern resolved by the subsidiary pattern remains on a wafer thereby adversely affecting the device or circuitry, it becomes possible to facilitate manufacturing and improve yield by using the subsidiary pattern having a great size.

As an example of the subsidiary pattern, in FIG. 12, layout pattern LP21 also shown in FIG. 10A and a plurality of dummy patterns DP21 are shown. As shown, it is also possible to add the subsidiary patterns of a relatively great size that resolves as dummy patterns DP21 for adjusting area ratio. In this case also, the size of dummy pattern DP21 is determined such that trace of dummy pattern DP21 does not ultimately remain on a wafer. Accordingly, when using dummy patterns DP21 that function as the area-ratio-adjusting subsidiary patterns for the hard mask process, the event where the patterns resolved by dummy patterns DP21 remain on a wafer thereby adversely affecting the device and circuitry can be avoided.

### Fourth Embodiment

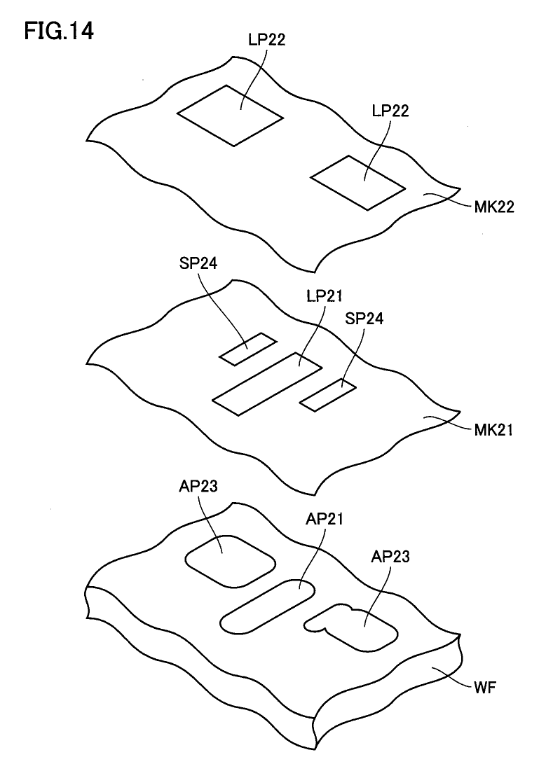

In the present embodiment, another example is shown where a subsidiary pattern is used in segmentation/distribution condition determining step (SDS8) shown in FIG. 4. As shown in FIGS. 13 and 14, layout pattern LP21 is distributed to mask MK21 as a first mask used in the first patterning of double patterning. Also, subsidiary patterns SP24 are formed in mask MK21, in addition to layout pattern LP21. Subsidiary patterns SP24 are formed to have a size that resolves on wafer WF as a substrate and leaves trace on the wafer in the first patterning where mask MK21 is used. Layout patterns LP22 are distributed to mask MK22 as a second mask used in the second patterning of double patterning.

Layout patterns LP22 formed on mask MK22 form patterns AP23 on wafer WF, which would overlap with the trace of subsidiary patterns SP24 formed on wafer WF in the first patterning. Specifically, the size and position of layout patterns LP22 are determined so that patterns overlapping with the trace of subsidiary patterns SP24 are formed. Hence, the trace of subsidiary patterns SP24 is completely included in patterns AP23 formed on wafer WF by layout patterns LP22. Alternatively, the area of the trace of subsidiary patterns SP24 outside patterns AP23 is small, or the area thereof inside patterns AP23 is small. As a result, the trace of subsidiary pattern SP24 does not pose a problem in the second patterning where mask MK22 is used.

As described above, to the portion (in the example described above, the portions where patterns AP23 are formed) to be a pattern in other mask or process (in the example described above, mask MK22 and the second patterning), subsidiary patterns SP24 that resolves on a wafer and leaves trace on the wafer can be arranged. Even when such subsidiary pattern SP24 is used, the shape of the wafer pattern is not ultimately affected, or affected slightly. Thus, the device and circuitry are not adversely affected, whereby manufacturing with an enhanced effect of subsidiary pattern placement is realized and yield is improved.

An example where subsidiary patterns SP24 in mask MK21 are overlapped with layout patterns LP22 of mask MK22 has been described in the present embodiment. On the other hand, when it is possible to overlap a subsidiary pattern in mask MK22 with a pattern of mask MK21, the similar effect can be achieved. When both manners can be combined, the combined use can clearly achieve the similar effect.

Furthermore, while an example where the layout patterns are distributed to two masks MK21 and MK22 has been described in the present embodiment, the number of the masks may be three or greater. In this case, the trace of resolved subsidiary pattern disappears, if the layout pattern formed in the mask overlaps with the trace of the subsidiary pattern in the patterning performed after the patterning where the mask with the subsidiary pattern is used. Specifically, when performing double patterning, the size and position of a layout pattern should be determined such that a layout pattern formed in a mask that is used in an n-th (n is an integer of at least two) patterning forms a structure that overlaps with the trace of a subsidiary pattern formed in an (n-k)-th (k is a positive integer smaller than n) patterning. This can achieve an effect that, while using a subsidiary pattern having the size resolvable on a wafer and capable of further increasing the depth of focus, the shape of the wafer pattern is not ultimately affected (or affected slightly).

### Fifth Embodiment

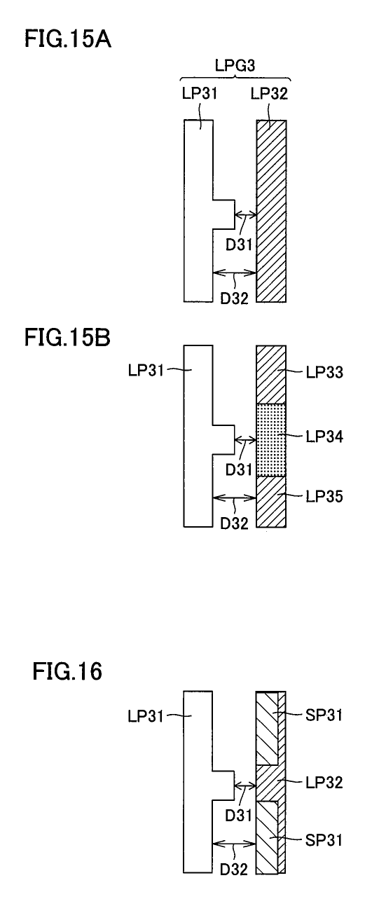

In the present embodiment, description will be given as to the relationship between layout pattern segmentation/distribution conditions and layout pattern manufacturing accuracy requirement, which should be considered in segmentation/distribution condition determining step (SDS8) shown in FIG. 4. As shown in FIG. 15A, a layout pattern group LPG3 is formed by a layout pattern LP31 having relatively high manufacturing accuracy requirement, and a layout pattern LP32, shown by a hatched portion, having relatively low manufacturing accuracy requirement. A distance D31 is a non-manufacturable distance with which layout patterns cannot separately be formed. A distance D32 is a preferable distance in manufacturing.

In the spacing between layout patterns LP31 and LP32 of layout pattern group LPG3, proximity of distance D31 is not preferable in manufacturing layout pattern group LPG3. On the other hand, proximity of distance D32 is preferable in manufacturing layout pattern group LPG3. In this case, according to the distribution method of distributing layout patterns LP31 and LP32 to different masks, though non-manufacturable distance D31 can be avoided, distance D32 preferable in manufacturing layout pattern group LPG3 will be lost.

An exemplary distribution method that is suitable for such a case is shown in FIG. 15B. As shown in FIG. 15B, layout pattern LP32 is segmented/distributed to layout patterns LP33-LP35. The portion near to layout pattern LP31 with non-manufacturable distance D31 is segmented as layout pattern LP34 and distributed to a mask that is different from the mask to which layout pattern LP31 is distributed. On the other hand, the portion near to layout pattern LP31 with preferable distance D32 is segmented as layout patterns LP33 and LP35 and distributed to the same mask to which layout pattern LP31 is distributed.

Specifically, in layout pattern group LPG3, layout pattern LP32 having relatively low manufacturing accuracy requirement is segmented to form layout patterns LP33-LP35. The segmented layout patterns LP33 and LP35, and layout pattern LP34 are distributed to different plurality of masks, in consideration of the distance from layout pattern LP31. In this manner, it becomes possible to ensure distance D32 preferable in manufacturing while avoiding non-manufacturable distance D31. Accordingly, manufacturing is facilitated and yield can be improved. It is apparent that the similar effect is attained when the present invention is applied to a case where the number of distribution is greater than two.

### Sixth Embodiment

In the present embodiment, description will be given as to the relationship between subsidiary pattern formation conditions and layout pattern manufacturing accuracy requirement, which should be considered in segmentation/distribution condition determining step (SDS8) shown in FIG. 4. As shown in FIG. 16, a layout pattern LP31 having relatively high manufacturing accuracy requirement and a layout pattern LP32 having relatively low manufacturing accuracy requirement are distributed to different masks, whereby a non-manufacturable distance D31 is avoided. Subsidiary patterns SP31 for layout pattern LP31 are produced such that spacing of a distance D32 preferable in manufacturing is attained relative to layout pattern LP31.

Specifically, subsidiary patterns SP31 are formed in the same mask where layout pattern LP31 having relatively high manufacturing accuracy requirement is formed, so as to overlap layout pattern LP 32 having relatively low manufacturing accuracy requirement in layout pattern group LPG3. Thus, it becomes possible to ensure distance D32 preferable in manufacturing while avoiding non-manufacturable distance D31. Accordingly, manufacturing is facilitated and yield can be improved. It is apparent that the similar effect is attained when the present invention is applied to a case where the number of distribution is greater than two.

As the subsidiary patterns for layout pattern LP31, subsidiary patterns of non-resolution size can be used. It is also possible to use subsidiary patterns of the resolvable size with which trace disappears in a later process, as in the third and fourth embodiments. It is also possible to arrange subsidiary patterns SP31 that resolve and leave trace on a wafer, as in the present embodiment. Similarly, it is also possible to arrange subsidiary patterns for layout pattern LP32 in the region of layout pattern LP31. However, when the subsidiary patterns affect the ultimate pattern on the wafer, it is effective to produce only subsidiary patterns SP31 for layout pattern LP31 so as to overlap on layout pattern LP32 that has relatively low manufacturing accuracy requirement as in the present embodiment.

### Seventh Embodiment

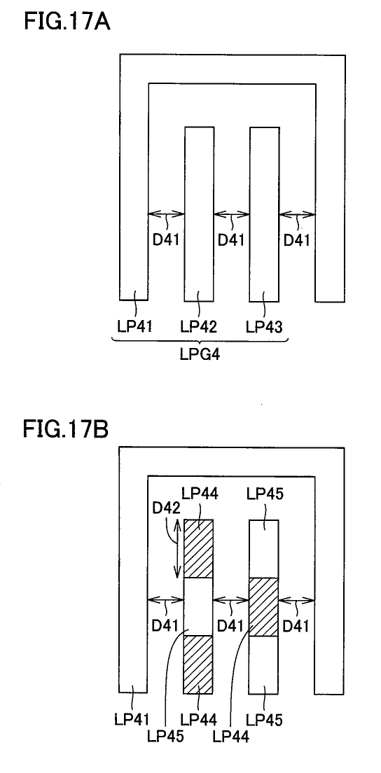

In the present embodiment, description will be given as to another example of the relationship between layout pattern segmentation/distribution conditions and layout pattern manufacturing accuracy requirement, which should be considered in segmentation/distribution condition determining step (SDS8) shown in FIG. 4. As shown in FIG. 17A, a layout pattern group LPG4 is formed by layout patterns LP41, LP42, and LP43. Layout pattern LP41 is formed in an inverted U shape. Layout patterns LP42 and LP43 are arranged so as to be surrounded by the U shape of layout pattern LP41. Distances between layout patterns LP41 and LP42, between LP42 and LP43, and between LP43 and LP41 are each a non-manufacturable distance D41 with which layout patterns cannot separately be formed.

Non-manufacturable distance D41 can be avoided if layout pattern LP41 is segmented. However, in the present embodiment, it is assumed that the manufacturing accuracy requirement of layout pattern LP41 is so high that layout pattern LP41 cannot be segmented. It is also assumed that layout patterns LP42 and LP43 have relatively low manufacturing accuracy requirement and can be segmented. Generally, even when a considerably long layout pattern is positioned at non-manufacturable distance D41 from an adjacent layout pattern and manufacturing is impossible, if that layout pattern has its side opposite to the adjacent layout pattern shortened, manufacturing is realized. The present embodiment utilizes this manner. Here, the side in the longitudinal direction of a certain layout pattern is referred to as an edge portion, and the length of the edge portion is referred to as an edge length.

Specifically, layout patterns LP42 and LP43 are arranged as a whole at the position where manufacturing is impossible, relative to layout pattern LP41. However, as shown in FIG. 17B, layout patterns LP42 and LP43 are segmented into LP44 and LP45. The segmented layout patterns LP44 and LP45 each have an edge length of a distance D42. It is assumed that a layout pattern having an edge length of distance D42 can be manufactured as separated from an adjacent layout pattern if the spacing between them is distance D41. Specifically, even layout patterns LP44 and LP45 are each at distance D41 relative to adjacent layout pattern LP41, the edge length of layout patterns LP44 and LP45 are manufacturing-possible edge lengths. Layout patterns LP42 and LP43 are segmented so as to attain manufacturing-possible edge lengths relative to layout pattern LP41.

As described above, layout patterns LP42 and LP43 can be segmented/distributed such that layout patterns LP42 and LP43 having considerably long edge lengths each attain an edge length (distance D42) that realizes manufacturing even with distance D41, which is a non-manufacturable distance when near to layout pattern LP41. Thus, even when positioned near at distance D41, manufacturing of layout patterns LP44 and LP45 becomes possible, and yield is improved. It is apparent that the similar effect is attained when the present invention is applied to a case where the number of distribution is greater than two.

### Eighth Embodiment

In the present embodiment, description will be given as to another example of using layout pattern group LPG4 shown in FIG. 17A in segmentation/distribution condition determining step (SDS8) shown in FIG. 4. As described in the seventh embodiment, the distance between each layout pattern shown in FIG. 8 is the distance with which layout patterns cannot separately be manufactured. In this case, non-manufacturable distance D41 can be avoided by segmenting the U-shaped layout pattern.

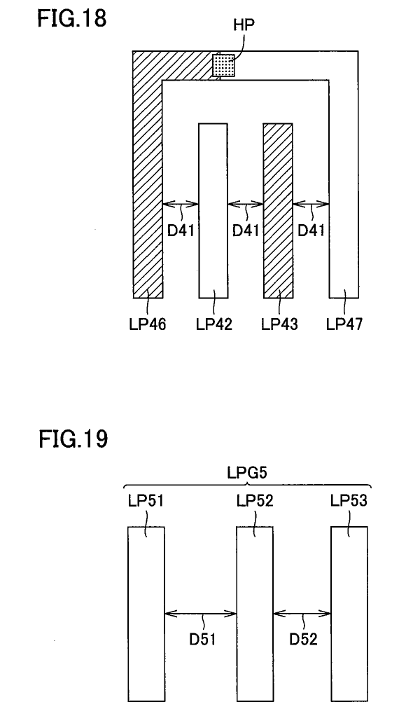

As shown in FIG. 18, on the U-shaped layout pattern, a hole pattern HP connected to an underlayer layout pattern and an interconnection is formed. Hole pattern HP and the interconnection pattern can be formed by the dual damascene method.

Here, when layout patterns are segmented, there may be a case where the layout pattern near the segmentation becomes slightly wide or narrow due to displacement of alignment. In such a case, as shown in FIG. 18, the U-shaped layout pattern is selectively segmented near hole pattern HP to obtain layout patterns LP46 and LP47. Then, when the interconnection becomes wide at the connection portion, the connection between hole pattern HP and the layout pattern can further be improved. Conversely, when the interconnection becomes narrow at the connection portion, yield can be improved without disconnecting for the dual damascene process. It is apparent that the similar effect is attained when the present invention is applied to a case where the hole pattern is not formed on the U-shaped layout pattern.

### Ninth Embodiment

In the present embodiment, description will be given as to a scheme of forming a plurality of layout patterns on an identical mask without segmenting them, in segmentation/distribution condition determining step (SDS8) shown in FIG. 4. As shown in FIG. 19, a layout pattern group LPG5 being the designed layout patterns is formed by layout patterns LP51, LP52, and LP53. Distances between layout patterns LP51 and LP52, and between layout patterns LP52 and LP53 are distances D51 and D52, respectively.

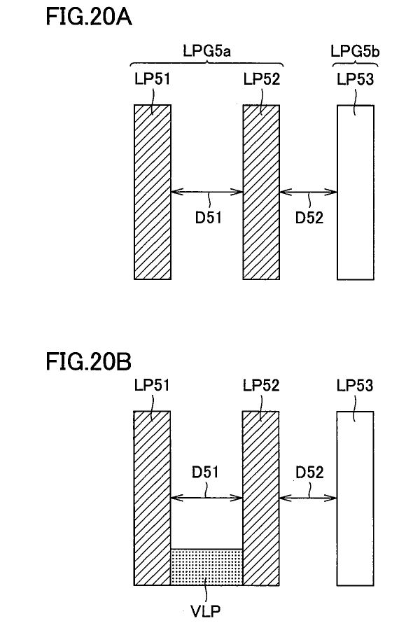

The designed layout patterns shown in FIG. 19 are distributed, as shown in FIG. 20A, to a layout pattern group LPG5a formed by layout patterns LP51 and LP52, and a layout pattern group LPG5b formed by layout pattern LP53. Specifically, adjacent layout patterns LP51 and LP52 are not distributed to different masks but formed on an identical mask. Such a distribution method can be realized as follows.

Specifically, in segmentation/distribution condition determining step (SDS8) shown in FIG. 4, as shown in FIG. 20B, a virtual layout pattern VLP is produced between layout patterns LP51 and LP52 so that virtual layout pattern VLP makes contact or overlaps with both layout patterns LP51 and LP52. Thus, layout patterns LP51 and LP52 are virtually connected. After layout patterns LP51 and LP52 are virtually connected, distribution of the layout pattern groups is performed. Virtually connected layout patterns LP51 and LP52 are treated as virtually one layout pattern. Therefore, layout patterns LP51 and LP52 will not be distributed to different masks. When segmentation is performed, it is performed so as not to segment layout patterns LP51 and LP52 with which virtual layout pattern VLP makes contact. Thus, distribution of layout patterns LP51 and LP52 to different masks can be prevented.

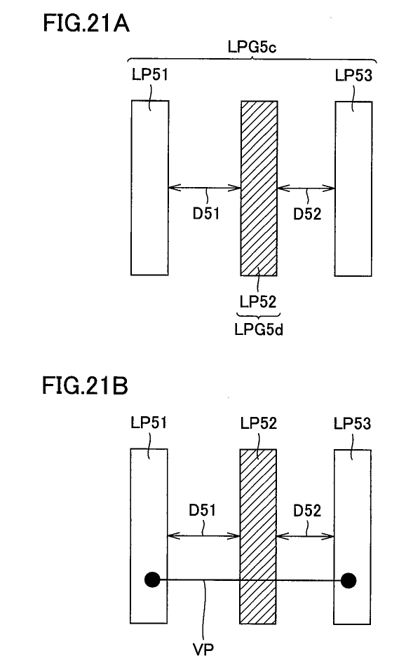

The designed layout pattern shown in FIG. 19 are distributed, as shown in FIG. 21A, to a layout pattern group LPG5c formed by layout patterns LP51 and LP53, and a layout pattern group LPG5d formed by layout pattern LP52. Specifically, layout patterns LP51 and LP53 not being adjacent to each other are not distributed to different masks but formed on the same mask. Such a distribution method can be realized as follows.

When layout patterns LP51 and LP53 are connected with a virtual layout pattern VLP as shown in FIG. 20B, three layout patterns including layout pattern LP52 are connected by virtual layout pattern VLP, and layout patterns LP51, LP52 and layout patterns LP52, LP53 cannot be distributed to separate masks.

In this case, as shown in FIG. 21B, a virtual path VP is produced between layout patterns LP51 and LP53 so that virtual path VP makes contact or overlaps with both layout patterns LP51 and LP53. (Alternatively, an internally-identical layout pattern ID is allotted such that layout patterns LP51 and LP53 are recognized as connected). Virtual path VP is different from virtual layout pattern VLP in that it only shows the opposing coordinates and that the layout patterns located at the opposing ends are connected. Regardless of what layout pattern crosses with a line formed by virtual pass VP, it is not taken into consideration.

Thus, layout patterns LP51 and LP53 are virtually connected. Thereafter, distribution of the layout patterns is performed. Virtually connected layout patterns LP51 and LP53 are treated as virtually one layout pattern. Therefore, layout patterns LP51 and LP53 will not be distributed to different masks. When segmentation is performed, it is performed so as not to segment layout patterns LP51 and LP53 with which virtual path VP makes contact. Thus, distribution of layout patterns LP51 and LP53 to different masks can be prevented.

As described above, since the layout pattern group is distributed to a plurality of masks, assuming that an adjacent, or not adjacent, plurality of layout patterns are virtually connected, it becomes possible to suppress distribution of the layout patterns to different masks. Thus, manufacturing is facilitated and yield is improved. It is apparent that the similar effect is attained when the present invention is applied to a case where the number of distribution is greater than two.

### Tenth Embodiment

In the present embodiment, description will be given as to a method of generating a candidate for a segmentation line for segmenting layout patterns in segmentation line candidate generating step (SDS7) shown in FIG. 4, and further determining the segmentation line in segmentation/distribution condition determining step (SDS8) shown in FIG. 4. The layout patterns are segmented by a segmentation line, and the position of the segmentation line can be set in accordance with the arrangement of other layout patterns adjacent to the segmented layout patterns.

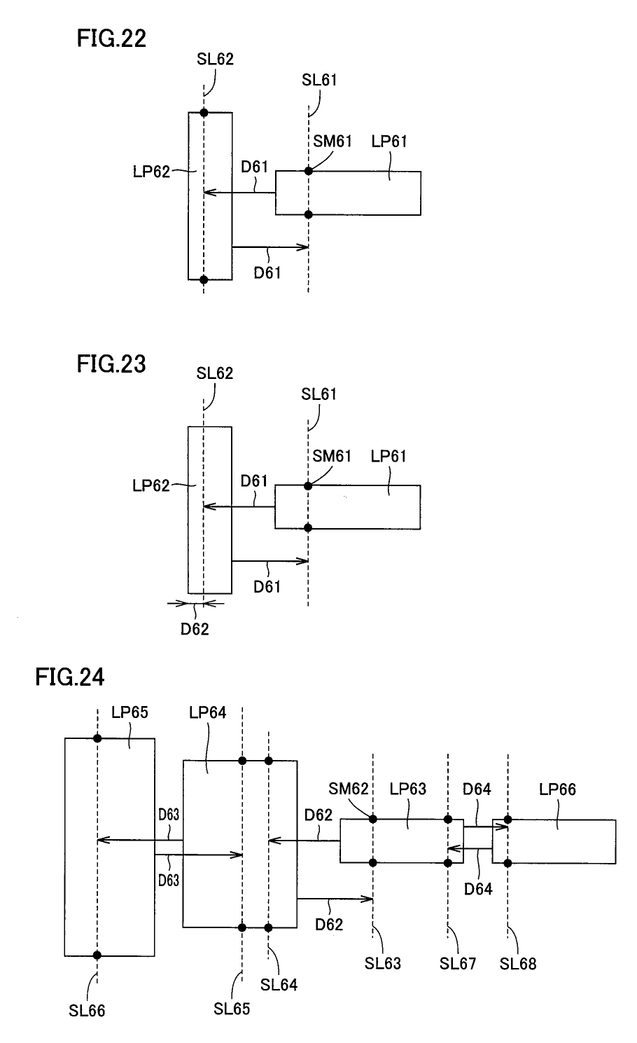

As shown in FIG. 22, the non-manufacturable layout pattern spacing for layout patterns LP61 and LP62 is a distance D61. Indicating the positions away by distance D61 from opposing sides of layout patterns LP61 and LP62 are broken lines as segmentation lines SL61 and SL62. The intersection points of broken lines SL61, SL62 and layout patterns LP61, LP62 are segmentation marks SM61 being the origin points for searching for the segmentation line. Thus, the number of segmentation line candidates can be limited, whereby load required for calculation processing for selecting the segmentation line can be reduced.

When the layout patterns are segmented so as to attain the size smaller than distance D62 being a manufacturing-impossible size, the layout patterns after being segmented cannot be manufactured. Accordingly, such a segmentation is undesirable.

In such a case, as shown in FIG. 23, segmentation marks being the segmentation line candidates are not provided at the intersections of segmentation line SL62 and the sides of layout pattern LP62. Thus, the segmentation line that would result in a manufacturing-impossible pattern size is eliminated from the segmentation line candidates, thereby limiting the number of the segmentation line candidates. Accordingly, load required for calculation processing for selecting the segmentation line can further be reduced.

The distance and size of non-manufacturable patterns are different depending on the layout pattern type (such as line ends, edge portions) and the size of layout patterns. Therefore, by providing candidates for the segmentation line according to such conditions, the segmentation line that would disappear in the method described referring to FIG. 23 can be left and the effect of segmentation can be enhanced. Such a method is realized as follows. Here, the side on the shorter side of the rectangle shape of a certain layout pattern is referred to as a line end, and the side on the longer side is referred to as an edge portion.

As shown in FIG. 24, the line end of layout pattern LP63 and the edge portion of layout pattern LP64 are near to each other. Therefore, at the intersection points of broken lines as segmentation lines SL63, SL64 positioned at distance D62 and the sides of layout patterns LP63, LP64, segmentation line candidates (segmentation marks SM62) are provided. On the other hand, layout patterns LP64 and LP65 are near to each other such that their edge portions are opposite to each other. Therefore, the segmentation line candidates are provided at the intersection points of the sides of layout patterns LP64, LP65 and broken lines as segmentation lines SL65, SL66 located at a distance different from distance D62, for example a greater distance D63, from the edge portions of layout patterns LP64 and LP65. Furthermore, layout patterns LP63 and LP66 are near to each other such that their line ends are opposite to each other. Therefore, the segmentation line candidates are provided at the intersection points of the sides of layout patterns LP63, LP66 and broken lines as segmentation lines SL67, SL68 located at a distance different from distances D62 and D63, for example a smaller distance D64, from the line ends of layout patterns LP63 and LP66. Thus, the effect of segmentation can be enhanced.

Furthermore, it is possible to arrange the segmentation marks in a limited number at more important positions, by arranging the segmentation marks referring to a layout pattern formed in a separate mask, or by arranging the segmentation marks at intersection points of a separately formed arbitrary layout pattern and layout patterns LP63-LP66 shown in FIG. 24. Furthermore, it is possible to control introduction of the segmentation line by specifying whether or not segmentation mark should be employed for each segmentation mark or by applying cost function weighting as to whether or not segmentation mark should be employed for each segmentation mark, depending on the conditions.

As a method of selecting the segmentation line, a method using lithography simulation, and an algorithm minimizing the cost of micro-patterns (see Japanese Patent Laying-Open No. 09-246158) can be applied. When applying these schemes, it may be possible to determine the cost function so as to minimize the total length of the segmentation lines with which spaces are not greater than a prescribed value. Here, if a length of the spaces not greater than a prescribed value being continuous is not greater than another prescribed value, that amount may not added to the total length of the segmentation lines. Thus, it becomes possible to reduce the effect of a proximate pattern that actually does not pose a problem. Furthermore, it is possible to employ as the cost function a value obtained by integrating the function having spaces as input along spaces.

As has been described in each embodiment, while each embodiment is effective even when practiced singularly, it becomes more effective when combined with other embodiment. Here, employing the total effect by use of a plurality of embodiments as a cost function, and obtaining a solution providing minimum or maximum cost function, an optimum value of combinational solution can be obtained, and a combination attaining the maximum effect can be carried out. Additionally, defining some of the embodiment to be essential, and evaluating the effect of the other embodiments by the cost function based on that the essential embodiments are practiced, and carrying out a combination attaining the maximum effect, it becomes possible to attain the effect of the essential embodiments while maximizing the effect of the other embodiments.

The semiconductor device manufacturing method and masks of the present invention are applicable particularly advantageously to an SoC (System on a Chip, an integrated circuit in which main features of a device (system) is integrated on one chip) and memory, using the process of post-32 nm node.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device manufacturing method using double patterning, comprising the steps of:
preparing a plurality of masks for use in said double patterning; and
performing said double patterning using said plurality of masks,
said step of preparing the plurality of masks including a step of distributing a group of layout patterns to the plurality of masks, in accordance with characteristics of exposure steps respectively using said plurality of masks, and in consideration of size of the layout patterns.

2. The semiconductor device manufacturing method according to claim 1, wherein
in said step of distributing the group of layout patterns, the group of layout patterns are distributed to the plurality of masks by taking as criterion a distance between adjacent ones of said layout patterns or largeness and smallness of width of said layout patterns.

3. A semiconductor device manufacturing method using double patterning, comprising the steps of:
preparing a plurality of masks for use in said double patterning; and
performing said double patterning using said plurality of masks,
said step of preparing the plurality of masks including a step of distributing a group of layout patterns to the plurality of masks, in accordance with characteristics of etching steps respectively using etching masks formed by using said plurality of masks, and in consideration of size of the layout patterns.

4. A semiconductor device manufacturing method using double patterning, comprising the steps of:
preparing a plurality of masks for use in said double patterning; and
performing said double patterning using said plurality of masks,
in at least one of said masks, a subsidiary pattern being formed in addition to a layout pattern, and
said subsidiary pattern having its size and position determined such that said subsidiary pattern resolves on a substrate, and such that a trace of the resolved subsidiary pattern disappears in a step after said subsidiary pattern has resolved.

5. A mask used in the semiconductor device manufacturing method according to claim 4.

6. A semiconductor device manufacturing method using double patterning, comprising the steps of:
preparing a plurality of masks for use in said double patterning; and
performing said double patterning using said plurality of masks,
in at least one of said masks, a subsidiary pattern being formed in addition to a layout pattern,
said subsidiary pattern being formed in a size resolvable on a substrate, and
in an n-th patterning (n being an integer not smaller than two) in said step of performing said double patterning, said layout pattern having its size and position determined such that said layout pattern forms a structure that overlaps with a trace of said subsidiary pattern formed in an (n-k) th patterning (k being a positive integer number smaller than n).

7. A semiconductor device manufacturing method using double patterning, comprising the steps of:
preparing a plurality of masks for use in said double patterning; and
performing said double patterning using said plurality of masks,
said step of preparing the plurality of masks including a step of segmenting layout patterns having relatively low manufacturing accuracy requirement among a group of layout patterns, and a step of distributing the segmented layout patterns to the plurality of masks.

8. A semiconductor device manufacturing method using double patterning, comprising the steps of:
preparing a plurality of masks for use in said double patterning; and
performing said double patterning using said plurality of masks,
said step of preparing the plurality of masks including a step of forming a subsidiary pattern in a mask where a layout pattern having relatively high manufacturing accuracy requirement among a group of layout patterns is formed, so that the subsidiary pattern overlaps with a layout pattern having relatively low manufacturing accuracy requirement.

9. A semiconductor device manufacturing method using double patterning, comprising the steps of:
preparing a plurality of masks for use in said double patterning; and
performing said double patterning using said plurality of masks,
said step of preparing the plurality of masks including a step of segmenting layout patterns arranged as a whole at a non-manufacturable position, so that the layout patterns attain a manufacturable edge length.

10. A semiconductor device manufacturing method using double patterning, comprising the steps of:
preparing a plurality of masks for use in said double patterning; and
performing said double patterning using said plurality of masks,
said step of preparing the plurality of masks including a step of distributing a group of layout patterns to the plurality of masks assuming that a plurality of the layout patterns are virtually connected.

11. A semiconductor device manufacturing method using double patterning, comprising the steps of:
preparing a plurality of masks for use in said double patterning; and
performing said double patterning using said plurality of masks,
said step of preparing the plurality of masks including a step of segmenting layout pattern, and
a position of a segmentation line segmenting said layout pattern is set in accordance with arrangement of other layout pattern adjacent to said layout pattern.
